(19) United States
(12) Patent Application Publication
(10) Pub. No.: US 2024/0074223 A1
(43) Pub. Date: Feb. 29, 2024

(54) LIGHT-EMITTING DEVICE AND METHOD FOR PREPARING THE SAME

(71) Applicant: TCL TECHNOLOGY GROUP CORPORATION, Huizhou (CN)

(72) Inventor: Tianfeng WANG, Huizhou, (CN)

(21) Appl. No.: 18/270,597

(22) PCT Filed: Dec. 27, 2021
(86) PCT No.: PCT/CN2021/141742

§ 371 Date: Jun. 30, 2023

(30) Foreign Application Priority Data
Dec. 31, 2020 (CN) 202011638368.2

(51) Int. Cl. H10K 50/115; H10K 50/16; H10K 71/00

(52) U.S. Cl. CPC H10K 50/115; H10K 50/16; H10K 71/00; H10K 2102/351

(57) ABSTRACT

The present application discloses a method for preparing a light-emitting device, including a following step: preparing a laminated composite structure of a quantum dot light-emitting layer and an electron transport layer between an anode and a cathode; the electron transport layer comprises a metal oxide transport material; and the laminated composite structure is irradiated by an ultraviolet light. In the method for preparing a light-emitting device, due that the light-emitting device includes the laminated composite structure of the quantum dot light-emitting layer and the electron transport layer, the electrons of oxygen in the metal oxide transport material in the electron transport layer are excited to form complexes with active metal elements such as a zinc in the quantum dot light-emitting layer, the internal physical structure defects and surface roughness of the electron transport layer are reduced.

### CROSS REFERENCE TO RELATED APPLICATION

The present application is a National Stage Application of International Patent Application No. PCT/CN2021/141742, filed on Dec. 27, 2021, which claims priority of a Chinese Patent Application, with Application No. 202011638368.2, filed on Dec. 31, 2020; the contents of which are incorporated herein by reference.

### TECHNICAL FIELD

The present application relates to the technical field of display devices, and more particularly to a light-emitting device and a method for preparing the same.

### BACKGROUND

Quantum dots are nanocrystalline particles with radius less than or close to the Bohr exciton radius, and the size is generally between one particle size. Quantum dots have quantum confinement effect and can emit fluorescence when being excited. Moreover, quantum dots have unique light-emitting characteristics such as wide excitation peak, narrow emission peak and adjustable light-emitting spectrum, which makes quantum dots materials have broad application prospects in the field of photoelectric light-emitting. Quantum dot light-emitting diode (QLED) is a new display technology that has been rapidly emerging in recent years. QLED is a device that uses colloidal quantum dots as a light-emitting layer, and introduces the quantum dot light-emitting layer between different conductive materials to obtain the required wavelength of light. QLED has the advantages of high color gamut, self-light-emitting, low starting current and fast response speed.

At present, in order to balance carrier injection in OLED devices, multi-layer device structure is generally adopted, and the quantum dot nanomaterial with a core-shell structure is mostly used in the quantum dot light-emitting layer. In the QLED, due to the organic surface ligands of the quantum dot nanoparticles and the fine core-shell structure inside the quantum dot nanoparticles, the annealing temperature cannot be too high, and the interface roughness of the formed quantum dot layer is high. In addition, the annealing temperature of the quantum dot layer also limits the annealing temperature of its adjacent electron transport layer ETL, such that the electron transport material is difficult to achieve a good crystallization temperature, which results in discontinuity of the internal structure of the electron transport layer, the transmission mobility of the electron is reduced, and the interface roughness is increased. However, the high interface roughness between the quantum dot light-emitting layer and the electron transport layer affects the continuity of carrier injection into the quantum dot light-emitting layer, and the injection efficiency is low, and the carrier injection performance is reduced. In addition, the charge accumulation center is easily formed at the interface gap, which accelerates the aging of the material and seriously affects the lifetime of the device.

### SUMMARY

One of the objects of an embodiment of the present application is to provide a light-emitting device and a method for preparing the same, in order to solve the problem that the interface fusion between the light-emitting layer and the electron transport layer is poor, which affects the electron injection efficiency and is easy to form charge accumulation.

In order to solve above technical problem, the embodiment of the present application adopts the technical solution as following:

In a first aspect, a method for preparing a light-emitting device is provided, and the method includes a following step:

preparing a laminated composite structure of a quantum dot light-emitting layer and an electron transport layer between an anode and a cathode;

the electron transport layer comprises a metal oxide transport material; and the laminated composite structure is irradiated by an ultraviolet light.

In a second aspect, a light-emitting device is provided, and the light-emitting device is prepared by above method.

The beneficial effects of the method for preparing the light-emitting device provided in the embodiment of the present application are that: the laminated composite structure of the quantum dot light-emitting layer (QD) and the electron transport layer (ETL) between the anode and the cathode, the laminated composite structure is irradiated by the ultraviolet light (UV), through the irradiating by the ultraviolet light, the electrons of oxygen in the metal oxide transport material in the electron transport layer are excited to form complexes with active metal elements such as a zinc in the quantum dot light-emitting layer. The formation of the complexes optimizes the interface between ETL-QD, the interface defect is reduced, which facilitates the injection of electrons from the electron transport layer into the quantum dot light-emitting layer. Moreover, due to the coordination between the metal of quantum dot material and the electrons of oxygen, the bonding defects inside the electron transport layer are also increased, and the electron mobility in the electron transport layer is improved. In addition, the formed complexes have a strong absorption effect to the UV of a certain wavelength, the temperature at the interface between the electron transport layer and the quantum dot light-emitting layer is increased, the bonding electrons are activated, the crystals in the electron transport layer is promoted to re-grow, the internal physical structure defects and surface roughness of the electron transport layer are reduced, and the interface bonding tightness between the QD-ETL is better, the electron accumulation center inside the electron transport layer and at the interface between the QD-ETL is reduced, the electron injection efficiency in the light-emitting layer is improved, the aging of materials is slowed down, and the device lifetime is improved.

The beneficial effects of the light-emitting device provided by the embodiment of the present application are that: due that the light-emitting device includes the laminated composite structure of the quantum dot light-emitting layer and the electron transport layer, the electrons of oxygen in the metal oxide transport material in the electron transport layer are excited to form complexes with active metal elements such as a zinc in the quantum dot light-emitting layer, the internal physical structure defects and surface roughness of the electron transport layer are reduced, the electron transport and migration efficiency is high, and the interface bonding between the quantum dot light-emitting layer and the electron transport layer is tight, the electron injection efficiency is high, the charge accumulation at the interface between the QD-ETL is avoided, the device stability is good, and the service lifetime is long.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a flowchart of a method for preparing a light-emitting device provided in an embodiment of the present application;

FIG. 2 is a schematic diagram of a positive structure of a quantum dot light-emitting diode provided by an embodiment of the present application;

FIG. 3 is a schematic diagram of an inverse structure of a quantum dot light-emitting diode provided by another embodiment of the present application;

FIG. 4 is an efficiency curve diagram of a quantum dot light-emitting diode provided by Example 1 and Comparison example 1 of the present application;

FIG. 5 is a current density-voltage curve diagram of a quantum dot light-emitting diode provided by Example 1 and Comparison example 1 of the present application; and

FIG. 6 is a luminance curve diagram of a quantum dot light-emitting diode provided by Example 1 and Comparison example 1 of the present application.

### DETAILED DESCRIPTION OF EMBODIMENTS

In order to make the purpose, the technical solution and the advantages of the present application be clearer and more understandable, the present application will be further described in detail below with reference to accompanying figures and embodiments. It should be understood that the specific embodiments described herein are merely intended to illustrate but not to limit the present application.

In the present application, the term “and/or” describes the association relationship of the associated object, indicating that there can be three kinds of relationships, for example, A and/or B, can mean: the existence of A alone, the existence of both A and B, and the existence of B alone. Where A and B can be singular or plural.

In the present application, “at least one” means one or more, and “a plurality of” means two or more. “At least one of the following”, or similar expressions thereof, means any combination of such terms, including any combination of single or plural terms. For example, “at least one of a, b, or c”, or, “at least one of a,b, and c”, can represent: a, b, c, a-b (i.e., a and b), a-c, b-c, or a-b-c, where a, b, and c can be single or multiple, respectively.

It should be understood that, value of serial number of the steps in the aforesaid embodiment doesn't mean a sequencing of execution sequences of the steps, the execution sequence of each of the steps should be determined by functionalities and internal logics of the steps themselves, and shouldn't be regarded as limitation to an implementation process of the embodiment of the present application. The terms used in embodiments of the present application are for the sole purpose of describing specific embodiments and are not intended to limit the present application. The terms “a” and “the” in the singular form as used in the embodiment of the present application and the accompanying claims are also intended to include the majority form, unless the context clearly indicates otherwise.

In order to illustrate the technical solution described in the present application, the following are detailed in conjunction with specific drawings and embodiments.

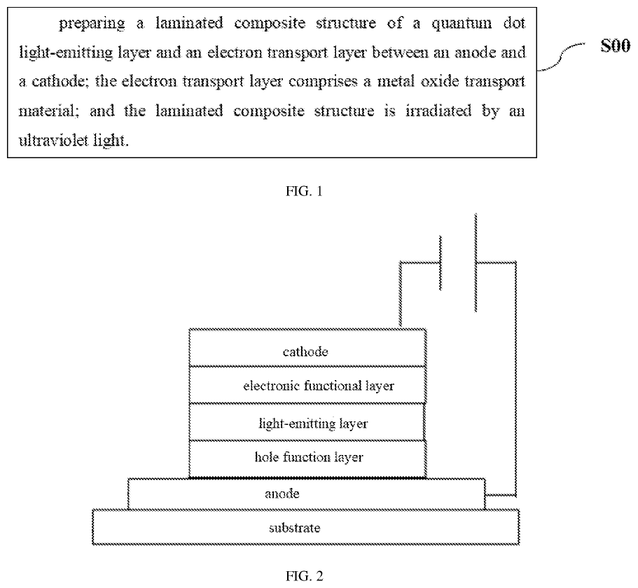

As shown in FIG. 1, a first aspect of an embodiment of the present application provides a method for preparing a light-emitting device, including a following step:

S00; preparing a laminated composite structure of a quantum dot light-emitting layer and an electron transport layer between an anode and a cathode;

the electron transport layer comprises a metal oxide transport material; and the laminated composite structure is irradiated by an ultraviolet light.

In the method for preparing a light-emitting device provided by the first aspect of an embodiment of the present application, the laminated composite structure of the quantum dot light-emitting layer (QD) and the electron transport layer (ETL) between the anode and the cathode, the laminated composite structure is irradiated by the ultraviolet light (UV), through the irradiating by the ultraviolet light, the electrons of oxygen in the metal oxide transport material in the electron transport layer are excited to form complexes with active metal elements such as a zinc in the quantum dot light-emitting layer. The formation of the complexes optimizes the interface between ETL-QD, the interface defect is reduced, which facilitates the injection of electrons from the electron transport layer into the quantum dot light-emitting layer. Moreover, due to the coordination between the metal of quantum dot material and the electrons of oxygen, the bonding defects inside the electron transport layer are also increased, and the electron mobility in the electron transport layer is improved. In addition, the formed complexes have a strong absorption effect to the UV of a certain wavelength, the temperature at the interface between the electron transport layer and the quantum dot light-emitting layer is increased, the bonding electrons are activated, the crystals in the electron transport layer is promoted to re-grow, the internal physical structure defects and surface roughness of the electron transport layer are reduced, and the interface bonding tightness between the QD-ETL is better, the electron accumulation center inside the electron transport layer and at the interface between the QD-ETL is reduced, the electron injection efficiency in the light-emitting layer is improved, the aging of materials is slowed down, and the device lifetime is improved.

In some embodiments, the quantum dot light-emitting layer includes a quantum dot material with a core-shell structure, and the shell layer of the quantum dot material contains a zinc element. Since most of the current quantum dot synthesis uses elements of group II-VI, Zn element and the elements of group VI have better matching in terms of lattice matching and band gap, which can cover the entire visible light waveband. Moreover, the shell layer of the quantum dot material containing zinc element has suitable chemical activity, high flexibility and controllability, wide band gap, good exciton binding, and high quantum efficiency; and water oxygen stability is good. In addition, zinc has a better and more stable coordination effect with the electrons of oxygen. Through UV irradiation, the electrons of oxygen of the metal oxide transport material in the electron transport layer are excited, and it is easy to form a complex with the Zn element in QD, that is, the ZnO complex. The formation of ZnO complex is conducive to electron injection and improves electron mobility in the electron transport layer. At the same time, ZnO complex has a strong absorption effect on the wavelength of ultraviolet light, which is conducive to be activated to form bonding electrons, the crystals in the electron transport layer is re-grown, the internal physical structure defects and surface roughness of the electron transport layer are reduced, which is conducive to electron injection, the electron accumulation is reduced, the aging of materials is slowed down, and the device lifetime is improved.

In some embodiments, the step of irradiating by the ultraviolet light includes: irradiating the laminated composite structure for 10 to 60 minutes under conditions of an ultraviolet light wavelength of 250˜420 nm and a light wave density of 10˜300 mJ/cm². The conditions of irradiating by the ultraviolet light provided by the embodiment of the present application can better promote the coordination of the electrons of oxygen in the metal oxide transport material in the ETL and metal elements such as a zinc in the quantum dot light-emitting layer, which not only optimizes the interface gap between the electron transport layer and the quantum dot light-emitting layer, improves the electron migration injection efficiency, but also better increases the internal bonding of ETL and promotes the re-growth of internal crystals. The internal crystal structure defects and surface roughness are reduced, and the electron mobility is improved.

In some embodiments, the step of irradiating by the ultraviolet light includes: the ultraviolet light is irradiated from a side of the electron transport layer. In the electron transport layer of the embodiment of the present application, the metal oxide electron transport material and the ZnO and other complexes formed have a strong absorption effect on ultraviolet and visible light. The ultraviolet light is irradiated from a side of the electron transport layer, and most of the light wave energy is absorbed by the electron transport material and the ZnO and other complexes formed at the interface between the QD-ETL. It can reduce the destructive effect of ultraviolet light on the material in the quantum dot layer and avoid the influence of ultraviolet radiation energy on the properties of the quantum dot material during irradiation.

In some embodiments, conditions of irradiating by the ultraviolet light include: a H₂O content is less than 1 ppm, and a temperature is 80-120° C. In the embodiment of the present application, the irradiating by the ultraviolet light is performed in the environment where the H₂O content is less than 1 ppm, and the temperature is 80-120° C., so as to avoid the hydrolysis of the surface of the quantum dot material in the irradiating treatment process caused by excessive water content in the environment, which will affect the material properties. At the same time, the heating environment of 80120° C. is conducive to promoting the bonding between the excited electrons of oxygen of and zinc ions, and is also conducive to the activation of bonding electrons.

In some embodiments, the metal oxide transport material is at least one selected from the group consisting of ZnO, TiO₂, Fe₂O₃, SnO₂, and Ta₂O₃; these metal oxide materials have high electron mobility, and the excited electrons of oxygen have good coordination effect with zinc in the shell layer of the QD. In some embodiments, the metal oxide transport material is one, two, or more materials selected from the group consisting of ZnO, TiO₂, Fe₂O₃, SnO₂, and Ta₂O₃.

In some embodiments, the metal oxide transport material is at least one selected from the group consisting of ZnO, TiO₂, Fe₂O₃, SnO₂, and Ta₂O₃ doped with a metal element, and the metal element is at least one selected from the group consisting of an aluminum, a magnesium, a lithium, a lanthanum, a yttrium, a manganese, a gallium, an iron, a chromium, and a cobalt. The metal oxide transport material of the present application is doped with aluminum, magnesium, lithium, lanthanum, yttrium, manganese, gallium, iron, chromium, cobalt and other metal elements, which is conducive to improving the electron transport and migration efficiency of the material. In some embodiments, the metal oxide transport material may be doped with one, two, or more metal element selected from the group consisting of an aluminum, a magnesium, a lithium, a lanthanum, a yttrium, a manganese, a gallium, an iron, a chromium, and a cobalt.

In some embodiments, a particle size of the metal transport material is less than or equal to 10 nm; the transport material with a small particle size is not only more favorable to form an electron transport layer that has a dense, uniform thickness and flat surface; the transport material with a small particle size has a larger specific surface area, which can produce more electrons of oxygen after ultraviolet excitation to coordinate with zinc atoms in the shell layer of the quantum dot material, so as to play a better interface optimization, the electron migration transport injection is improved, and charge accumulation and other effects are avoided.

In some embodiments, the shell layer of the quantum dot material comprises an alloy material formed by at least one or at least two selected from the group consisting of ZnS, ZnSe, ZnTe, CdZnS and ZnCdSe. These shell materials all contain a zinc element, the activity of the zinc element is high, and the zinc element has a good coordination effect with the excited electrons of oxygen in the electron transport material.

In some specific embodiments, when the shell layer of the quantum dot material is made of the ZnS, a wavelength of irradiating by the ultraviolet light is 250-355 nm, and the light wave density is 50˜150 mJ/cm². In the embodiment of the present application, when the shell layer is made of the ZnS, the ZnS bond energy is about 3.5 eV, the ZnO bond energy is about 3.3 eV, and the bonding charge transfer of electron transport material such as the ZnS and the ZnO in the shell of quantum dot material can be caused under the conditions that the wavelength is 250-355 nm and the light wave density is 50-150 mJ/cm², such that the zinc element in the shell layer has a better coordination effect with the oxygen element in the electron transport material to form a complex of the electron transport material and the quantum dot material.

In some specific embodiments, when the shell layer of the quantum dot material is made of the ZnSe, a wavelength of irradiating by the ultraviolet light is 280-375 nm, and the light wave density is 30-120 mJ/cm². In the embodiment of the present application, when the shell layer is made of the ZnSe, the ZnSe bond energy is about 2.9 eV, the ZnO bond energy is about 3.3 eV, and the bonding charge transfer of electron transport material such as the ZnSe and the ZnO in the shell of quantum dot material can be caused under the conditions that the wavelength is 280-375 nm and the light wave density is 30-120 mJ/cm², such that the zinc element in the shell layer has a better coordination effect with the oxygen element in the electron transport material to form a complex of the electron transport material and the quantum dot material.

In some specific embodiments, when the shell layer of the quantum dot material is made of the ZnSeS, a wavelength of irradiating by the ultraviolet light is 250-375 nm, and the light wave density is 30-150 mJ/cm². In the embodiment of the present application, when the shell layer is made of the ZnSeS, the ZnSeS bond energy is about 2.7 eV, the ZnO bond energy is about 3.3 eV, and the bonding charge transfer of electron transport material such as the ZnSeS and the ZnO in the shell of quantum dot material can be caused under the conditions that the wavelength is 250-375 nm and the light wave density is 30-150 mJ/cm², such that the zinc element in the shell layer has a better coordination effect with the oxygen element in the electron transport material to form a complex of the electron transport material and the quantum dot material.

In some embodiments, a thickness of the electron transport layer is 10-200 nm, the thickness meets the requirements of property and structure of the device. In some specific embodiments, when the thickness of the electron transport layer is less than 80 nm, the duration of UV irradiation treatment is 15 minutes to 45 minutes. In the embodiment of the present application, when the thickness of the electron transport layer is less than 80 nm, the light wave energy is relatively easy to penetrate the low-thickness material layer, and the irradiation time required to achieve the treatment effect is short, and the duration of ultraviolet irradiation treatment is suitable for 15 minutes to 45 minutes. In other specific embodiments, when the thickness of the electron transport layer is higher than 80 nm, the duration of UV irradiation treatment is 30 minutes to 90 minutes. In the embodiment of the present application, when the thickness of the electron transport layer is higher than 80 nm, the light wave energy is difficult to penetrate the thicker material layer, and the irradiation time required to achieve the treatment effect is longer, and the duration of ultraviolet irradiation treatment is suitable for 30 minutes to 90 minutes.

In some embodiments, a thickness of the quantum dot light-emitting layer is 8-100 nm, the thickness meets the requirements of property and structure of the device.

In some embodiments, the outer layer thickness of the quantum dot material is 0.2-6.0 nm, which ensures the stability of the quantum dot inner layer material and the carrier injection effect, while ensuring the coordination effect of the zinc element in the shell layer and the oxygen element in the metal oxide transport material.

In some embodiments, the method for preparing the light-emitting device further includes a step of preparing a hole injection layer and a hole transport layer between the anode and the quantum dot light-emitting layer.

In some embodiments, a laminated composite structure of a quantum dot light-emitting layer and an electron transport layer is prepared between the anode and the cathode by using a thin film transfer method, including the steps: depositing a quantum dot light-emitting layer and an electron transport layer on a substrate successively; transferring a laminated composite film of the quantum dot light-emitting layer and the electron transport layer to a substrate prepared with a cathode after the composite film of the quantum dot light-emitting layer and electron transport layer is irradiated by ultraviolet light; preparing a hole transport layer, a hole injection layer and an anode onto a surface of the quantum dot light-emitting layer successively, to obtain a light-emitting device with an inverse structure. Alternatively, transferring a laminated composite film of the quantum dot light-emitting layer and the electron transport layer to a substrate prepared with a cathode, a hole injection layer and a hole transport layer successively, and preparing a cathode on a surface of the electron transport layer, to obtain a light-emitting device with a positive structure.

In other embodiments, a laminated composite structure of a quantum dot light-emitting layer and an electron transport layer is prepared between the anode and the cathode by using a solution deposition method. In the light-emitting device with a positive structure, the steps include: preparing an anode on a substrate; depositing to prepare a hole injection layer on a side surface of the anode away from the substrate; depositing to prepare a hole transport layer on a side surface of the hole injection layer away from the anode; depositing to prepare a quantum dot light-emitting layer on a side surface of the hole transport layer; preparing an electron transport layer on a surface of the quantum dot light-emitting layer away from the hole transport layer, irradiating the electron transport layer by an ultraviolet light to obtain a laminated composite structure of the quantum dot light-emitting layer and the electron transport layer; depositing to prepare a cathode on the surface of the electron transport layer to obtain the photoelectric device. In the light-emitting device with an inverse structure, the steps include: preparing the cathode on the substrate; preparing the electron transport layer on a surface of the cathode; preparing the quantum dot light-emitting layer is on the side surface of the electron transport layer away from the cathode, irradiating the quantum dot light-emitting layer by the ultraviolet light to obtain a laminated composite structure of the quantum dot light-emitting layer and the electron transport layer; and preparing a hole transport layer, a hole injection layer and an anode successively on a side surface of the quantum dot light-emitting layer away from the electron transport layer to obtain the photoelectric device.

In some specific embodiments, the method for preparing a light-emitting device in the embodiment of the present application consists of steps:

S10; obtaining a substrate with an anode deposited;

S20; producing a hole transport layer onto a surface of the anode;

S30; depositing a quantum dot light-emitting layer onto the hole transport layer;

S40; depositing an electron transport layer onto the quantum dot light-emitting layer;

S50; irradiating the electron transport layer by an ultraviolet light; and

S60; evaporating a cathode onto the electron transport layer to obtain the light-emitting device.

In the embodiment, in step S10, in order to obtain a high-quality light-emitting device, the ITO substrate needs to perform a pretreatment process. The basic specific treatment steps include: cleaning the ITO conductive glass with a detergent, initially removing a stain existing on the surface, followed by ultrasonic cleaning in deionized water, acetone, anhydrous ethanol, deionized water respectively for 20 min to remove the impurities existing on the surface, and finally drying with a high purity nitrogen to obtain the positive electrode of ITO.

In the embodiment, in step S20, the step of producing the hole transport layer includes: depositing the solution of the prepared hole transport material on the substrate to form a film by drip coating, spin coating, soaking, coating, printing, evaporating and other processes; controlling a thickness of the film by adjusting the concentration of the solution, the deposition rate and the deposition time, then performing a thermal annealing at an appropriate temperature.

In the embodiment, in step S30, the step of depositing a quantum dot light-emitting layer onto the hole transport layer includes: depositing the light-emitting substance solution with a certain concentration on the substrate on which the hole transport layer has been deposited to form a film by drip coating, spin coating, soaking, coating, printing, evaporating and other processes; controlling a thickness of the film by adjusting the concentration of the solution, the deposition rate and the deposition time, the thickness is about 20-60 nm; and drying at an appropriate temperature.

In the embodiment, in step S40, the step of depositing an electron transport layer on a quantum dot light-emitting layer includes: the electron transport layer is a metal oxide transport material: depositing the metal oxide transport material solution with a certain concentration on the substrate on which the quantum dot light-emitting layer has been deposited to form a film by drip coating, spin coating, soaking, coating, printing, evaporating and other processes; controlling a thickness of the film by adjusting the concentration of the solution, the deposition rate (such as the rotational rate between 3000 and 5000 rpm) and the deposition time, the thickness is about 20-60 nm; then annealing at 150° C.˜200° C. to form a film, and fully removing the solvent.

In the embodiment, in step S50, when the H₂O content is less than 1 ppm and the temperature is 80-120° C., the electron transport layer is irradiated vertically for 10˜60 min by ultraviolet light with wavelength of 250˜420 nm and light wave density of 10˜300 mJ/cm².

In the embodiment, in step S60, the step of preparing the cathode preparation includes: placing the substrate after deposition of each functional layer in the evaporation chamber and hot-evaporating a layer of 60-100 nm metal silver or aluminum as the cathode through the mask plate.

In some embodiments, performing an encapsulating treatment to the obtained QLED device, and the encapsulating treatment can be performed by a common machine encapsulating or a manual encapsulating. In some embodiments, in the encapsulating environment, the oxygen and water content are less than 0.1 ppm to ensure device stability.

The second aspect of the embodiment of the present application provides a light-emitting device, which is prepared by the method described above.

In the light-emitting device provided by the embodiment of the second aspect of the present application, due that the light-emitting device includes the laminated composite structure of the quantum dot light-emitting layer and the electron transport layer, the electrons of oxygen in the metal oxide transport material in the electron transport layer are excited to form complexes with active metal elements such as a zinc in the quantum dot light-emitting layer, the internal physical structure defects and surface roughness of the electron transport layer are reduced, the electron transport and migration efficiency is high, and the interface bonding between the quantum dot light-emitting layer and the electron transport layer is tight, the electron injection efficiency is high, the charge accumulation at the interface between the QD-ETL is avoided, the device stability is good, and the service lifetime is long.

In the embodiments of the present application, the light-emitting device is not limited by the device structure, which can be a device with a positive structure or a device with an inverse structure.

In one embodiment, the light-emitting device with the positive structure includes a laminated structure of an anode and a cathode arranged relative to each other, a light-emitting layer arranged between the anode and the cathode, and an anode arranged on a substrate. In some embodiments, a hole injection layer, a hole transport layer, an electron barrier layer and other hole function layers can be arranged between the anode and the light-emitting layer. As shown in FIG. 2, an electronic functional layers such as an electron transport layer, an electron injection layer and a hole blocking layer can be further arranged between the cathode and the light-emitting layer. In some specific embodiments of the device with the positive structure, the light-emitting device includes a substrate, an anode arranged on the surface of the substrate, a hole transport layer arranged on the surface of the anode, a light-emitting layer arranged on the surface of the hole transport layer, an electron transport layer arranged on the surface of the light-emitting layer, and a cathode arranged on the surface of the electron transport layer.

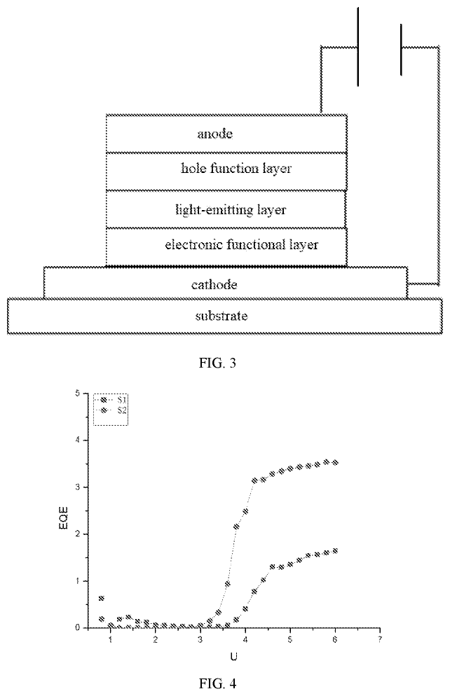

In one embodiment, the light-emitting device with the inverse structure includes a laminated structure of an anode and a cathode arranged relative to each other, a light-emitting layer arranged between the anode and the cathode, and a cathode arranged on the substrate. In some embodiments, a hole injection layer, a hole transport layer, an electron barrier layer and other hole function layers can be arranged between the anode and the light-emitting layer. As shown in FIG. 3, an electronic functional layers such as an electron transport layer, an electron injection layer and a hole blocking layer can be further arranged between the cathode and the light-emitting layer. In some specific embodiments of the device with the inverse structure, the light-emitting device includes a substrate, a cathode arranged on the surface of the substrate, an electron transport layer arranged on the surface of the cathode, a light-emitting layer arranged on the surface of the electron transport layer, a hole transport layer arranged on the surface of the light-emitting layer, and an anode arranged on the surface of the hole transport layer.

In some embodiments, the selection of the substrate is not limited, which can select a rigid substrate or a flexible substrate. In some specific embodiments, the rigid substrate includes, but is not limited to, one or more selected from the group consisting of a glass and a metal foil. In some specific embodiments, the flexible substrate includes but is not limited to one or more selected from the group consisting of a polyethylene terephthalate (PET), a polyethylene terephthalate (PEN), a polyether ether ketone (PEEK), a polystyrene (PS), a polyether sulfone (PES), a polycarbonate (PC), a polyaryl ester (PAT), a polyaryl ester (PAR), a polyimide (PI), a polyvinyl chloride (PV), a polyether ethyl Ene (PE), a polyvinylpyrrolidone (PVP), and a textile fiber.

In some embodiments, the selection of the anode material is not limited, which can select from a doped metal oxide, including but not limited to one or more selected from the group consisting of indium doped tin oxide (ITO), fluorine doped tin oxide (FTO), antimony doped tin oxide (ATO), aluminum doped zinc oxide (AZO), gallium doped zinc oxide (GZO), indium doped zinc oxide (IZO), magnesium doped zinc oxide (MZO), and aluminum doped magnesium oxide (AMO). The anode material can select from a composite electrode with a metal sandwiched between doped or undoped transparent metal oxides, including but not limited to one or more selected from the group consisting of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂.

In some embodiments, the hole injection layer includes, but is not limited to, one or more selected from the group consisting of an organic hole injection material, a doped or undoped transition metal oxide, and a doped or undoped metal-sulfur compound. In some specific embodiments, the organic hole injection material includes but is not limited to one or more selected from the group consisting of poly (3,4-thiophene ethylene 2 oxygen)-polystyrene sulfonic acid (PEDOT: PSS), copper phthalocyanine (CuPc), 2,3,5,6-four fluorine-7,7′, 8,8′-four cyanide quinone-2 methane (F4-TCNQ), 2,3,6,7,10,11-six cyano-1, 4,5,8,9,12-hexazepines (HATCN). In some specific embodiments, the transition metal oxide includes, but is not limited to, one or more selected from the group consisting of MoO₃, VO₂, WO₃, CrO₃, and CuO. In some specific embodiments, the metal-sulfur compound includes, but is not limited to, one or more selected from a groupof MoS₂, MoSe₂, WS₂, WSSe₂, and CuS.

In some embodiments, the hole transport layer may be selected from an organic material with hole transport capability and/or an inorganic material with hole transport capability. In some specific embodiments, the organic material with hole transport capability includes, but is not limited to, one or more selected from the group consisting of poly (9,9-dioctylfluoreno-co-N-(4-butylphenyl) diphenylamine) (TFB), polyvinyl carbazole (PVK), poly (N,N′ bis (4-butylphenyl)-N, N′-bis (phenyl) benzidine) (poly-TPD), poly (9,9-dioctylfluoreno-co-di-N, n-phenyl-1,4-phenylenediamine) (PFB), 4,4,4″-tri (carbazol-9-yl) triphenylamine (TCTA), 4,4′-bis (9-carbazole) biphenyl (CBP), N,N′-diphenyl-N,N′-bis(3-methylphenyl)-1,1′-biphenyl-4,4′-diamine (TPD), and N,N′-diphenyl-N,N′-(1-naphthyl)-1,1′-biphenyl-4,4′-diamine (NPB). In some specific embodiments, the inorganic material with hole transport capability includes, but is not limited to, one or more selected from the group consisting of doped graphene, undoped graphene, C60, doped or undoped MoO3, VO2, WO3, CrO3, CuO, MoS2, MoSe2, WS2, WSe2, and CuS.

In some embodiments, the light-emitting layer includes a quantum dot material, the quantum dot material is a quantum dot material with a core-shell structure, and the shell layer of the quantum dot material contains a zinc element. In some specific embodiments, the outer shell layer of the quantum dot material is an alloy material formed by at least one or two selected from the group consisting of ZnS, ZnSe, ZnTe, CdZnS, and ZnCdSe. In some embodiments, the particle size of the quantum dot material ranges from 2 to 10 nm, and the particle size is too small, the film forming property of the quantum dot material becomes poor, and the energy resonance transfer effect between the quantum dot particles is significant, which is not conducive to the application of the material; the particle size is too large, the quantum effect of the quantum dot material is weakened, so that the photoelectric performance of the material is decreased.

In some embodiments, the material of the electron transport layer adopts the metal oxide transport material described above.

In some embodiments, the cathode material may be one or more of various conductive carbon materials, a conductive metal oxide material, or a metallic material. In some specific embodiments, the conductive carbon materials includes, but is not limited to, doped or undoped carbon nanotube, doped or undoped graphene, doped or undoped graphene oxide, C60, graphite, carbon fiber, polyspace carbon, or mixtures thereof. In some specific embodiments, the conductive metal oxide material includes, but is not limited to, ITO, FTO, ATO, AZO, or mixtures thereof. In some specific embodiments, the metal material includes, but is not limited to, Al, Ag, Cu, Mo, Au, or their alloys; the form of the metal material includes but is not limited to a dense film, a nanowire, a nanosphere, a nanorod, a nanocone, a nano-hollow sphere, or mixtures thereof; In some embodiments, the cathode is made of Ag or Al.

In order to enable the above implementation details and operations of the present application to be clearly understood by those skilled in the art and to significantly reflect the progressive performance of light emitting device and the method for preparing the same in the embodiments of the present application, the above technical solutions are illustrated by several embodiments.

### Example 1

A light-emitting diode includes the following preparing steps:
(1) providing a ITO anode and pre-treating the anode: ultrasonic treating for 15 min using an alkaline detergent solution (PH>10), ultrasonic treating for 15 min twice using a deionized water, ultrasonic cleaning for 15 min using an isopropyl alcohol, then drying for 2 hours at 80° C., and ultraviolet treating for 15 min using an ozone.
(2) forming a hole injection layer on the anode of the step (1): spin coating the PEDOT:PSS solution on the anode under the electric field, annealing at 150° C. for 15 min after 5000 rpm spin coating for 40 s to form a hole injection layer; a direction of the electric field is perpendicular to the anode and towards the hole injection layer, and the electric field intensity is 10⁴ V/cm.
(3) forming a hole transport layer on the hole injection layer: spin coating the TFB solution (concentration: 8 mg/mL, solvent: chlorobenol) on the hole injection layer, annealing at 80° C. for 30 min after 3000 rpm spin coating for 30 s to form a hole transport layer; a direction of the electric field is perpendicular to the anode and towards the hole transport layer, and the electric field intensity is 10⁴ V/cm.
(4) forming a light-emitting layer on the hole transport layer: taking the CdSe/ZnS quantum dot solution (concentration: 30 mg/mL, solvent; n-octane), spin coating the CdSe/ZnS quantum dot solution on the hole transport layer at 3000 rpm in the glove box (water oxygen content is less than 0.1 ppm), to form a light-emitting layer.
(5) forming an electron transport layer on the light-emitting layer: spin coating the ZnO solution (concentration: 45 mg/mL, solvent: ethanol) on the light-emitting layer in the glove box (water oxygen content is less than 0.1 ppm), annealing at 80° C. for 30 min after 3000 rpm spin coating for 30 s to form an electron transport layer.
(6) performing UV treatment on the electron transport layer under the environment where the H₂O content is less than 1 ppm and the temperature is 80° C., and vertically irradiating from a side of the electron transport layer, the UV wavelength is 320 nm, the light intensity is 300 mJ/cm², and the time of UV treatment is 30 min
(7) forming a cathode on the electron transport layer: evaporating the Al on the electron transport layer using the evaporation method, forming an Al electrode with a thickness of 60-150 nm to obtain a light-emitting diode.

### Example 2

A light-emitting diode includes the following preparing steps:
(1) preparing a quantum dot light-emitting layer on a substrate: taking the CdSe/ZnS quantum dot solution (concentration: 30 mg/mL, solvent; n-octane), spin coating the CdSe/ZnS quantum dot solution on the substrate at 3000 rpm in the glove box (water oxygen content is less than 0.1 ppm), to form a light-emitting layer.
(2) preparing an electron transport layer on the light-emitting layer: spin coating the ZnO solution (concentration: 45 mg/mL, solvent: ethanol) on the light-emitting layer in the glove box (water oxygen content is less than 0.1 ppm), annealing at 80° C. for 30 min after 3000 rpm spin coating for 30 s to form an electron transport layer.
(3) irradiating by ultraviolet light with UV wavelength of 320 nm and intensity of 300 mJ/cm 2 to a laminated composite structure of the quantum dot light-emitting layer and the electron transport layer for 30 min under the environment where the H₂O content is less than 1 ppm and the temperature is 80° C., to obtain a laminated composite film of the quantum dot light-emitting layer and the electron transport layer.
(4) transferring the laminated composite film of the quantum dot light-emitting layer and electron transport layer to the substrate successively prepared with the anode, the hole injection layer and the hole transport layer, evaporating the Al on the electron transport layer using the evaporation method on the surface of the electron transport layer to form an Al electrode with a thickness of 60-150 nm to obtain a light-emitting diode.

### Example 3

The difference between the preparation steps of a light-emitting diode of the Example 3 and Example 1 is that: in step (5), spin coating the TiO₂ solution on the light-emitting layer.

### Example 4

The difference between the preparation steps of a light-emitting diode of the Example 4 and Example 1 is that: in step (5), using the ZnMgO.

### Example 5

The difference between the preparation steps of a light-emitting diode of the Example 5 and Example 1 is that: in step (4), using the CdSe/ZnSe; in step (6), the UV wavelength is 320 nm, the light intensity is 100 mJ/cm², and the time of UV treatment is 30 min.

### Example 6

The difference between the preparation steps of a light-emitting diode of the Example 6 and Example 1 is that: in step (4), using the CdSe/ZnSeS; in step (6), the UV wavelength is 320 nm, the light intensity is 120 mJ/cm², and the time of UV treatment is 30 min.

### Comparison Example 1

The difference between the preparation steps of a light-emitting diode of the Comparison example 1 and Example 1 is that: there is not treated with UV in step (6).

In order to verify the progressiveness of the embodiments of the present application, the following performance tests are conducted for Examples 1 to 6 and the Comparison example 1. The test indicators and test methods are as follows, and the test results are shown in Table 1 and FIGS. 4 to 6:

(1) Constructing a Current Density-Voltage (J-V) Curve

In the environment of room temperature and air humidity of 30%-60%, LabView is used to control the QE PRO spectrometer, the efficiency test system constructed by the Keithley 2400 and Keithley 6485 is tested, and the voltage, current and other parameters is measured to construct the J-V curve.

(2) External Quantum Efficiency (EQE)

The ratio (%) of electron-hole logarithm injected into quantum dots into the number of the photons emitted, is an important parameter to measure the merits of electroluminescent devices, which can be determined by using EQE optical testing instrument. The specific calculation formula is as follows:

$$EQE = η e η r χ \frac{{K}_{R}}{{K}_{R} + {K}_{NR}}$$

Where, ηe is an optical output coupling efficiency, ηr is a ratio of a number of recombination carriers to a number of injected carriers, χ is a ratio of a number of photon-generating excitons to the total exciton number, K_{R} is the rate of the radiating process, and K_{NR} is the rate of the non-radiating process. The test conditions: at room temperature, air humidity of 30-60%.

(3) Constructing Luminance-Voltage (L-V) Curve The luminance (L) is a ratio of a luminous flux of a light-emitting surface in a specified direction to an area perpendicular to the specified direction (cd/m²). The linear silicon optical tube system PDB-C613 calibrated and controlled by the LabView is used to measure, and the device brightness is calculated by combining the spectrum and visual function, and L-V curve is constructed according to the change of brightness with voltage.

(4) Lifetime Test

In the following embodiments, the lifetime test adopts the constant current method. Driven by a constant current of 50 mA/cm², the silicon optical system is used to test the brightness change of the device, the the time LT95 of device brightness starts from the highest point and decays to the highest brightness 95% is recorded, then the lifetime of the device 1000 nit LT95S is extrapolated from the empirical formula.

1000 nit LT95=(L_{Max}/1000)^{1.7}×LT95

This method is convenient to compare the lifetime of devices with different brightness levels, and has wide application in practical optoelectronic devices.

TABLE 1

| | | electron | | |
|---|---|---|---|---|
| Device | quantum | transport layer | | |
| number | dot shell | (particle size) | EQE(%) | LT95(hour) |
| Comparison | ZnS | ZnO(5.5 nm) | 1.80% | 7.19 |
| example 1 | | | | |
| Example 1 | ZnS | ZnO(5.5 nm) | 3.50% | 13 |
| Example 2 | ZnS | ZnO(5.5 nm) | 2.80% | 10.8 |
| Example 3 | ZnS | TiO₂(5.5 nm) | 4.70% | 6.8 |
| Example 4 | ZnS | ZnMgO(5.5 nm) | 5.20% | 22.3 |
| Example 5 | ZnSe | ZnO(5.5 nm) | 2.50% | 9.3 |
| Example 6 | ZnSeS | ZnO(5.5 nm) | 3.20% | 14.1 |

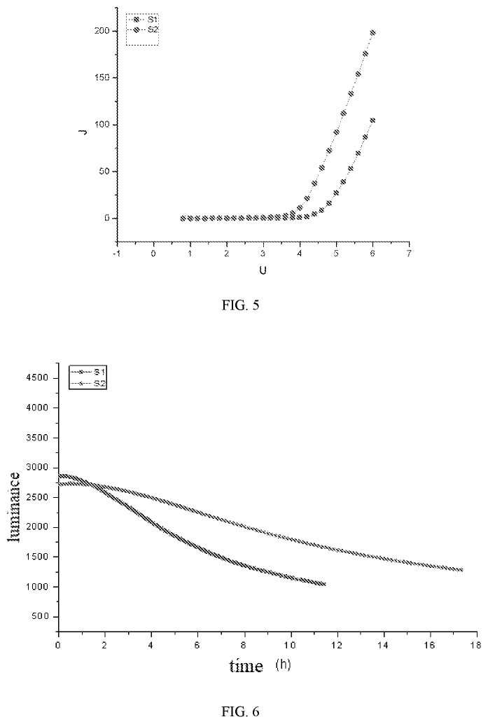

From the test results of Table of Examples 1-6 and Comparison example 1, as well as the efficiency curve (horizontal coordinate is voltage, vertical coordinate is external quantum efficiency) of Embodiments 1 (S2) and Comparison example 1 in FIG. 4, current density-voltage curve (horizontal coordinate is voltage, vertical coordinate is current density) in FIG. 5, and brightness curve (horizontal coordinate is time, vertical coordinate is brightness) in FIG. 6, The devices after UV treatment in embodiments 1 to 6 of the present application have better luminous efficiency and longer luminous lifetime than the devices in Comparison example 1 without UV treatment.

The above are optional embodiments of the present application only and are not intended to limit the present application. For those skilled in the art, the present application is subject to various changes and variations. Any modification, equivalent replacement, improvement, etc. made within the spirit and principles of the present application shall be included in the scope of the claims of the present application.

1. A method for preparing a light-emitting device, comprising a following step:
preparing a laminated composite structure of a quantum dot light-emitting layer and an electron transport layer between an anode and a cathode;
wherein the electron transport layer comprises a metal oxide transport material; and the laminated composite structure is irradiated by an ultraviolet light.

2. The method for preparing the light-emitting device according to claim 1, wherein the quantum dot light-emitting layer comprises a quantum dot material with a core-shell structure, and a shell layer of the quantum dot material contains a zinc element.

3. The method for preparing the light-emitting device according to claim 1, wherein the step of irradiating by the ultraviolet light comprises: irradiating the laminated composite structure for 10 to 60 minutes under conditions of an ultraviolet light wavelength of 250˜420 nm and a light wave density of 10˜300 mJ/cm².

4. The method for preparing the light-emitting device according to claim 3, wherein the step of irradiating by the ultraviolet light comprises: irradiating by the ultraviolet light from a side of the electron transport layer.

5. The method for preparing the light-emitting device according to claim 3, wherein conditions of irradiating by the ultraviolet light comprise: under an environment of a H₂O content being less than 1 ppm, and a temperature being 80-120° C.

6. The method for preparing the light-emitting device according to claim 3, wherein the metal oxide transport material is at least one selected from the group consisting of ZnO, TiO₂, Fe₂O₃, SnO₂, and Ta₂O₃.

7. The method for preparing the light-emitting device according to claim 3, wherein the metal oxide transport material is at least one selected from the group consisting of ZnO, TiO₂, Fe₂O₃, SnO₂, and Ta₂O₃ doped with a metal element, and the metal element is at least one selected from the group consisting of aluminum, magnesium, lithium, lanthanum, yttrium, manganese, gallium, iron, chromium, and cobalt.

8. The method for preparing the light-emitting device according to claim 3, wherein a particle size of the metal transport material is less than or equal to 10 nm.

9. The method for preparing the light-emitting device according to claim 6, wherein the shell layer of the quantum dot material comprises an alloy material formed by at least one or at least two selected from the group consisting of ZnS, ZnSe, ZnTe, CdZnS and ZnCdSe.

10. The method for preparing the light-emitting device according to claim 9, wherein when the shell layer of the quantum dot material is made of the ZnS, a wavelength of irradiating by the ultraviolet light is 250-355 nm, and the light wave density is 50˜150 mJ/cm².

11. The method for preparing the light-emitting device according to claim 6, wherein a thickness of the electron transport layer is 10-200 nm.

12. The method for preparing the light-emitting device according to claim 6, wherein a thickness of the quantum dot light-emitting layer is 8-100 nm.

13. The method for preparing the light-emitting device according to claim 6, wherein a thickness of the shell layer of the quantum dot material is 0.2-6.0 nm.

14. The method for preparing the light-emitting device according to claim 11, wherein when the thickness of the electron transport layer is less than 80 nm, a duration of irradiating by the ultraviolet light is 15 minutes to 45 minutes.

15. The method for preparing the light-emitting device according to claim 14, further comprising a step of preparing a hole injection layer and a hole transport layer between the anode and the quantum dot light-emitting layer.

16. A light-emitting device, wherein the light-emitting device is prepared by a method comprising a following step:
preparing a laminated composite structure of a quantum dot light-emitting layer and an electron transport layer between an anode and a cathode;
wherein the electron transport layer comprises a metal oxide transport material; and the laminated composite structure is irradiated by an ultraviolet light.

17. The method for preparing the light-emitting device according to claim 9, wherein when the shell layer of the quantum dot material is made of the ZnSe, a wavelength of irradiating by the ultraviolet light is 280-375 nm, and the light wave density is 30-120 mJ/cm².

18. The method for preparing the light-emitting device according to claim 9, wherein when the shell layer of the quantum dot material is made of the ZnSeS, a wavelength of irradiating by the ultraviolet light is 250-375 nm, and the light wave density is 30-150 mJ/cm².

19. The method for preparing the light-emitting device according to claim 2, wherein the step of irradiating by the ultraviolet light comprises: irradiating the laminated composite structure for 10 to 60 minutes under conditions of an ultraviolet light wavelength of 250˜420 nm and a light wave density of 10˜300 mJ/cm².

20. The method for preparing the light-emitting device according to claim 11, wherein when the thickness of the electron transport layer is higher than 80 nm, a duration of irradiating by the ultraviolet light is 30 minutes to 90 minutes
